(19) United States
(12) Patent Application Publication
(10) Pub. No.: US 2023/0282497 A1
(43) Pub. Date: Sep. 7, 2023

(54) FEEDER MEMBER AND WAFER PLACEMENT TABLE

(71) Applicant: NGK Insulators, Ltd., Nagoya-City (JP)

(72) Inventors: Mitsuru KOJIMA, Handa City (JP); Hiroshi TAKEBAYASHI, Handa City (JP)

(73) Assignee: NGK Insulators, Ltd., Nagoya-City (JP)

(21) Appl. No.: 18/164,824

(22) Filed: Feb. 6, 2023

(30) Foreign Application Priority Data
Mar. 3, 2022 (JP) 2022-032564

(51) Int. Cl. H01L 21/67; H01L 21/683

(52) U.S. Cl. CPC H01L 21/67103; H01L 21/67248; H01L 21/6831

(57) ABSTRACT

A feeder member includes an electrode-side terminal, an insert, a connector, and a cable. The electrode-side terminal is made of a high-melting-point metal containing material, and is joined to an electrode embedded in a ceramic base. Each of the insert, the connector and the cable is made of a Cu containing material. The insert has a joined portion that is directly joined to the electrode-side terminal without using a brazing material, and a hole portion that is provided on a side opposite to the joined portion. The connector has a socket portion that is electrically connected to a conductive member differing from the feeder member, and a recessed portion that is provided on a side opposite to the socket portion. The cable has one end joined to the hole portion of the insert, and the other end joined to the recessed portion of the connector.

### BACKGROUND OF THE INVENTION

### 1. Field of the Invention

The present invention relates to a feeder member and a wafer placement table.

### 2. Description of the Related Art

A semiconductor manufacturing apparatus is used to attract a wafer and heat/cool the wafer in, for example, an etching device, an ion implantation device, or an electron-beam exposure device. As such a semiconductor manufacturing apparatus, an apparatus including a ceramic electrostatic chuck that has a wafer placement surface and that has built therein an electrostatic electrode and a heater electrode, and including a metal base member that is bonded to a surface of the electrostatic chuck on a side opposite to the wafer placement surface is known. Patent Literature 1 discloses a feeder member that is used to supply electricity to electrodes (an electrostatic electrode and a heater electrode) embedded in an electrostatic chuck of such a semiconductor manufacturing apparatus. The feeder member includes an electrode-side terminal that is joined to the electrodes, a flexible cable whose upper end is connected to the electrode-side terminal, and a female connector that is connected to a lower end of the cable. A male connector of an external device is connected to the female connector. According to the feeder member, even if a force that pushes toward the electrodes acts upon the female connector, the cable is flexed and absorbs the force, as a result of which the electrostatic chuck can be prevented from being damaged.

### CITATION LIST

### Patent Literature

PTL 1: Japanese Unexamined Patent Application Publication No. 2013-191626

### SUMMARY OF THE INVENTION

When forming the feeder member described above, a cable insertion hole may be provided in the electrode-side terminal made of Mo, and the upper end of the cable made of Cu may be inserted into the hole to join them by electrode-beam welding or laser-beam welding. However, in such a welding method, since the temperature does not rise to a temperature close to the melting point of Mo, an alloy of Mo and Cu is not easily formed and the melted Cu of the cable may only be in contact with an inner surface of the hole of the electrode-side terminal without being joined thereto. In addition, when solidifying the melted Cu, a pore may be formed at an interface between Cu and Mo. Therefore, a sufficient joining strength between the electrode-side terminal made of Mo and the cable made of Cu may not be obtained.

The present invention has been made to solve such problems, and a primary object of the present invention is to provide a feeder member having sufficient strength.

A feeder member of the present invention is a feeder member that is used to supply electricity to an electrode embedded in a ceramic base, and includes an electrode-side terminal that is made of a high-melting-point metal containing material, and that is joined to the electrode; an insert that is made of a Cu containing material, and that has a joined portion and a hole portion, the joined portion being directly joined to the electrode-side terminal without using a brazing material, the hole portion being provided on a side opposite to the joined portion; a connector that is made of a Cu containing material, and that has a joint portion and a recessed portion, the joint portion being electrically connected to a conductive member differing from the feeder member, the recessed portion being provided on a side opposite to the joint portion; and a cable that is made of a Cu containing material, has one end joined to the insert with the one end being inserted in the hole portion of the insert, and has the other end joined to the connector with the other end being inserted in the recessed portion of the connector.

In the feeder member, the joined portion of the insert made of a Cu containing material is directly joined without using a brazing material to the electrode-side terminal made of a high-melting-point metal containing material. Therefore, the electrode-side terminal and the insert are joined to each other with sufficient strength. One end of the cable made of a Cu containing material is joined with the one end being inserted in the hole portion of the insert, and the other end of the cable is joined with the other end being inserted in the recessed portion of the connector made of a Cu containing material. Since these joinings are joinings between members made of a Cu containing material, sufficient strength can be obtained. Therefore, the feeder member has sufficient strength.

In the feeder member of the present invention, it is preferable that the electrode-side terminal is made of a Mo containing material. This makes it possible to, when the ceramic base is made of an alumina containing material, prevent, for example, a crack from being formed between the electrode-side terminal and the ceramic base. This is because, since the coefficient of thermal expansion of alumina and the coefficient of thermal expansion of Mo are close to each other, stress that is produced by a difference in thermal expansion is reduced.

A wafer placement table of the present invention includes a ceramic base that has, at a surface thereof, a wafer placement surface; an electrode that is embedded in the ceramic base; and a feeder member that is inserted into a surface of the ceramic base on a side opposite to the wafer placement surface, and that is joined to the electrode, in which the feeder member is the feeder member of the present invention above, and the electrode-side terminal is joined to the electrode.

In the wafer placement table, the joined portion of the insert made of a Cu containing material is directly joined without using a brazing material to the electrode-side terminal made of a high-melting-point metal containing material. Therefore, the electrode-side terminal and the insert are joined to each other with sufficient strength. One end of the cable made of a Cu containing material is joined with the one end being inserted in the hole portion of the insert, and the other end of the cable is joined with the other end being inserted in the recessed portion of the connector made of a Cu containing material. Since these joinings are joinings between members made of a Cu containing material, sufficient strength can be obtained. Therefore, the feeder member has sufficient strength.

In the wafer placement table of the present invention, it is preferable that the ceramic base is made of an alumina containing material, and that the electrode-side terminal is made of a Mo containing material. This makes it possible to prevent, for example, a crack from being formed between the electrode-side terminal and the ceramic base. This is because, since the coefficient of thermal expansion of alumina and the coefficient of thermal expansion of Mo are close to each other, stress that is produced by a difference in thermal expansion is reduced.

### BRIEF DESCRIPTION OF THE DRAWINGS

FIG. 1 is a cross-sectional view schematically showing a wafer placement table 10.

FIG. 2 is a vertical cross-sectional view showing a schematic structure of a feeder member 50.

FIGS. 3A to 3D show steps of manufacturing the feeder member 50.

FIG. 4 is a vertical cross-sectional view showing a schematic structure of a feeder member 150.

FIG. 5 is a graph showing the rupture strength of an embodiment and the rupture strength of a comparative form.

### DETAILED DESCRIPTION OF THE INVENTION

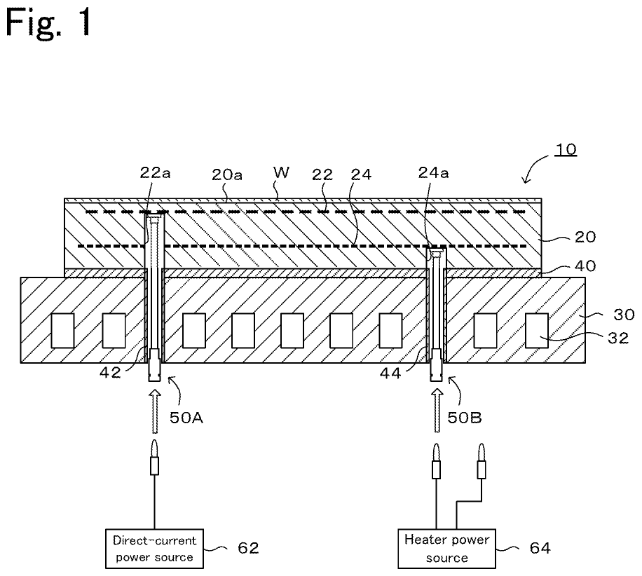

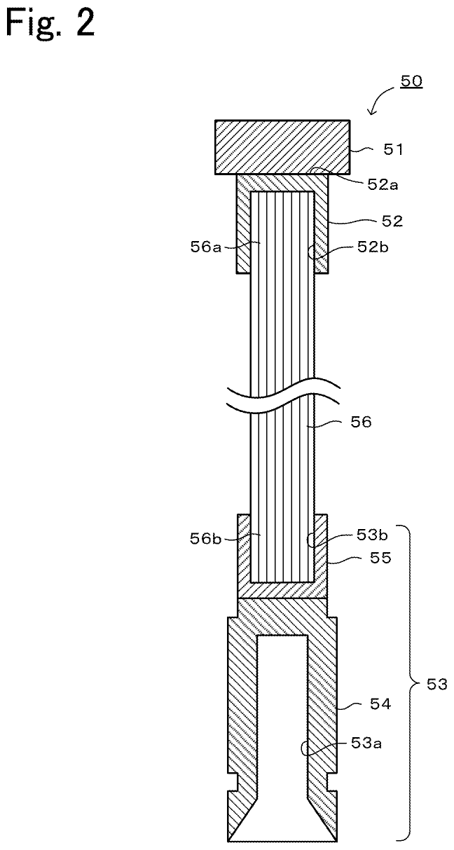

FIG. 1 is a cross-sectional view showing a schematic structure of a wafer placement table 10 of the present embodiment (cross-sectional view when the wafer placement table 10 is cut by a plane including a central axis of the wafer placement table 10), and FIG. 2 is a vertical cross-sectional view of a schematic structure of a feeder member 50 (cross-sectional view when the feeder member 50 is cut by a plane including a central axis of the feeder member 50). Note that, in the description below, up, down, left, right, front, and back may be used. However, up, down, left, right, front, and back are merely relative positional relationships.

The wafer placement table 10 is used for processing a wafer W. As shown in FIG. 1, the wafer placement table 10 includes a ceramic base 20, an electrostatic electrode 22, a heater electrode 24, a cooling base 30, a joined layer 40, and feeder members 50A and 50B.

The ceramic base 20 is a disc-shaped member having, at its surface, a wafer placement surface 20a. The ceramic base 20 is made of a ceramic containing material. The ceramic containing material is a material whose main component is ceramic, and may contain, in addition to ceramic, for example, a component that is derived from a sintering additive (for example, a rare-earth element), or an unavoidable component. “Main component” means that the proportion is 50 mass % of the entire mass or greater (the same shall apply below). The ceramic is, for example, alumina or aluminum nitride.

The electrostatic electrode 22 and the heater electrode 24 are embedded in the ceramic base 20. The electrostatic electrode 22 is embedded on a side closer than the heater electrode 24 to the wafer placement surface 20a. The electrodes 22 and 24 are made of, for example, a material containing W, Mo, WC, MoC, or the like. The electrostatic electrode 22 is a disc-shaped or mesh single-pole electrostatic electrode. In the ceramic base 20, a layer disposed above the electrostatic electrode 22 functions as a dielectric layer. An electrostatic-attraction direct-current power source 62 is connected to the electrostatic electrode 22 through the feeder member 50A. The heater electrode 24 is wired in a one-stroke pattern from one end to the other end so as to extend over the entire wafer placement surface 20a in plan view. A heater power source 64 is connected to one end of the heater electrode 24 through the feeder member 50B. Similarly to the one end of the heater electrode 24, although not shown, the other end of the heater electrode 24 is also connected to the heater power source 64 through the feeder member 50B.

The cooling base 30 is a disc-shaped member including a refrigerant flow path 32 in which a refrigerant can circulate. The refrigerant flow path 32 is formed in a one-stroke pattern from one end to the other end so as to extend over the entire surface of the ceramic base 20 in plan view. One end and the other end of the refrigerant flow path 32 are connected to a refrigerant circulation pump (not shown) having the function of regulating the temperature of a refrigerant. The cooling base 30 is made of, for example, a conductive material containing a metal. The conductive material is, for example, a composite material or a metal. The composite material is, for example, a metal matrix composite (MMC), and the MMC is, for example, a material containing Si, SiC, and Ti, or a material in which a SiC porous body is impregnated with Al and/or Si. The material containing Si, SiC, and Ti is called SiSiCTi, the material in which the SiC porous body is impregnated with Al is called AlSiC, and the material in which the SiC porous body is impregnated with Si is called SiSiC. The metal is, for example, Al, Ti, Mo, or an alloy thereof.

The joined layer 40 joins a lower surface of the ceramic base 20 and an upper surface of the cooling base 30. The joined layer 40 may be a metal joined layer made of, for example, solder or a metal brazing material. The metal joined layer is formed by, for example, TCB (thermal compression bonding). TCB refers to a publicly known method in which a metal joining material is interposed between two members to be joined and the two members are pressed and joined to each other while being heated to a temperature less than or equal to the solidus temperature of the metal joining material.

The feeder member 50A has its upper end joined to the electrostatic electrode 22 with the feeder member 50A extending via a through hole that extends through the cooling base 30 in an up-down direction and extending via a through hole that extends through the joined layer 40 in the up-down direction, and with the feeder member 50A being inserted in a through hole 22a that extends from the lower surface of the ceramic base 20 to the electrostatic electrode 22. An insulating tube 42 is inserted in the through hole that extends through the cooling base 30 in the up-down direction and in the through hole that extends through the joined layer 40 in the up-down direction. The feeder member 50A passes through the inside of the insulating tube 42.

The feeder member 50B has its upper end joined to the heater electrode 24 with the feeder member 50B extending via a through hole that extends through the cooling base 30 in the up-down direction and extending via a through hole that extends through the joined layer 40 in the up-down direction, and with the feeder member 50B being inserted in a through hole 24a that extends from the lower surface of the ceramic base 20 to the heater electrode 24. An insulating tube 44 is inserted in the through hole that extends through the cooling base 30 in the up-down direction and in the through hole that extends through the joined layer 40 in the up-down direction. The feeder member 50B passes through the inside of the insulating tube 44.

The feeder members 50A and 50B have the same structure except that their cable lengths differ from each other. Therefore, the feeder members 50A and 50B are described below as the feeder member 50 without distinguishing them.

As shown in FIG. 2, the feeder member 50 includes an electrode-side terminal 51, an insert 52, a connector 53, and a cable 56.

The electrode-side terminal 51 is a disc-shaped member made of a high-melting-point metal containing material. The high-melting-point metal containing material is a material whose main component is a metal having a high melting point, and may contain, in addition to a metal having a high melting point, for example, an unavoidable component or a component that is contained in the ceramic base 20. The metal having a high melting point is, for example, Mo or W. When the ceramic base 20 is made of an alumina containing material, the electrode-side terminal 51 is preferably made of a Mo containing material. The electrode-side terminal 51 is joined to an electrode (the electrostatic electrode 22 or the heater electrode 24) and the ceramic base 20 that is disposed around the electrode with a brazing material. The brazing material is, for example, an Au containing alloy. The Au containing alloy is, for example, an AuGe alloy, an AuSn alloy, or an AuSi alloy. When the electrode-side terminal 51 is made of a Mo containing material, an AuGe alloy is preferably used for the brazing material.

The insert 52 is made of a Cu containing material and is a columnar member. The Cu containing material is a material whose main component is Cu, and may contain, in addition to Cu, for example, an unavoidable component. The insert 52 has a joined portion 52a that is joined to the electrode-side terminal 51, and a hole portion 52b that is provided on a side opposite to the joined portion 52a. In the present embodiment, the joined portion 52a is an upper surface of a column, and is directly joined to the electrode-side terminal 51 without using a brazing material. Therefore, the strength of a joined part where the joined portion 52a and the electrode-side terminal 51 are joined to each other is sufficiently increased. When the joined part where the joined portion 52a and the electrode-side terminal 51 are joined to each other is seen in a SEM photograph, a gap cannot be seen at a joining interface, which is preferable.

The connector 53 is made of a Cu containing material, and has a socket portion 53a (corresponding to a joint portion in the present invention) and a recessed portion 53b. The socket portion 53a is provided on a lower side of the connector 53, and is electrically connected to a conductive member of an external device (such as the direct-current power source 62 or the heater power source 64). In the present embodiment, the socket portion 53a is a banana jack, and the conductive member of the external device is a banana plug that is inserted into the banana jack. The recessed portion 53b is a hole provided on an upper side of the connector 53. The connector 53 is one in which a lower member 54 having the socket portion 53a and an upper member 55 having the recessed portion 53b are joined to each other. The lower member 54 and the upper member 55 can be joined by, for example, soldering, electronic-beam welding, or laser-beam welding. Since the lower member 54 and the upper member 55 are each made of a Cu containing material, the strength of a welded portion where the members 54 and 55 are welded to each other is sufficiently increased.

The cable 56 is a flexible cable made of a Cu containing material. In the present embodiment, the cable 56 is a stranded wire of thin metal wires made of a Cu containing material. An upper end 56a of the cable 56 is joined to the insert 52 with the upper end 56a being inserted in the hole portion 52b of the insert 52. A lower end 56b of the cable 56 is joined to the connector 53 with the lower end 56b being inserted in the recessed portion 53b of the connector 53. The joining of the cable 56 and the insert 52 and the joining of the cable 56 and the connector 53 can be performed by, for example, electron-beam welding or laser-beam welding. Since the cable 56, the insert 52, and the connector 53 are each made of a Cu containing material, the strength of welded portions is sufficiently increased.

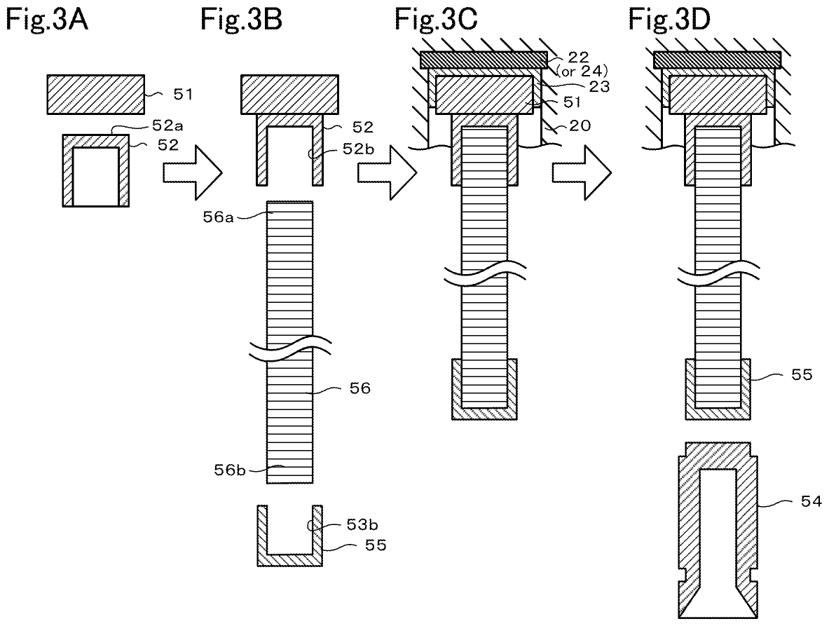

Next, an example of manufacturing a feeder member 50 (including an example of attaching the feeder member 50 to a corresponding one of the electrodes) is described by using FIGS. 3A to 3D. FIGS. 3A to 3D show steps of manufacturing the feeder member 50. Here, an electrode-side terminal 51 is made of a Mo containing material; and an insert 52, a connector 53 (a lower member 54 and an upper member 55), and a cable 56 are each made of a Cu containing material.

First, the electrode-side terminal 51 and the insert 52 are prepared, and a lower surface of the electrode-side terminal 51 and a joined portion 52a, which is an upper surface of the insert 52, are directly joined to each other (see FIG. 3A). They can be directly joined by, for example, a method disclosed in Japanese Patent No. 3602582. Note that it is possible to prepare a columnar body (without a hole portion 52b) instead of the insert 52, and to directly join the columnar body and the electrode-side terminal 51 to each other to thereafter form a hole portion 52b in the columnar body and form the columnar body as the insert 52.

Next, an upper end 56a of the cable 56 is inserted into and welded to the hole portion 52b provided in a lower surface of the insert 52, and a lower end 56b of the cable 56 is inserted into and welded to a recessed portion 53b of the upper member 55 (see FIG. 3B). The welding at this time can be, for example, electron-beam welding or laser-beam welding.

Next, the electrode-side terminal 51 is joined to an electrode (an electrostatic electrode 22 or a heater electrode 24) that is embedded in a ceramic base 20 and to the ceramic base 20 that is disposed around the electrode (see FIG. 3C). The joining at this time can be performed by using an Au containing alloy (for example, an AuGe alloy). This causes the electrode-side terminal 51 to be joined to the electrode and to the ceramic base 20 that is disposed around the electrode by a brazing joined layer 23.

Lastly, a lower surface of the upper member 55 and an upper surface of the lower member 54 are joined to each other (see FIG. 3D) to obtain the feeder member 50. The joining at this time can be performed by, for example, soldering, electron-beam welding, or laser-beam welding. Note that it is possible to provide the lower surface of the upper member 55 with a positioning small protrusion, provide the upper surface of the lower member 54 with a small hole that can be fitted to the small protrusion, and fit the small protrusion and the small hole to each other. This makes it possible to easily align the upper member 55 and the lower member 54 with respect to each other.

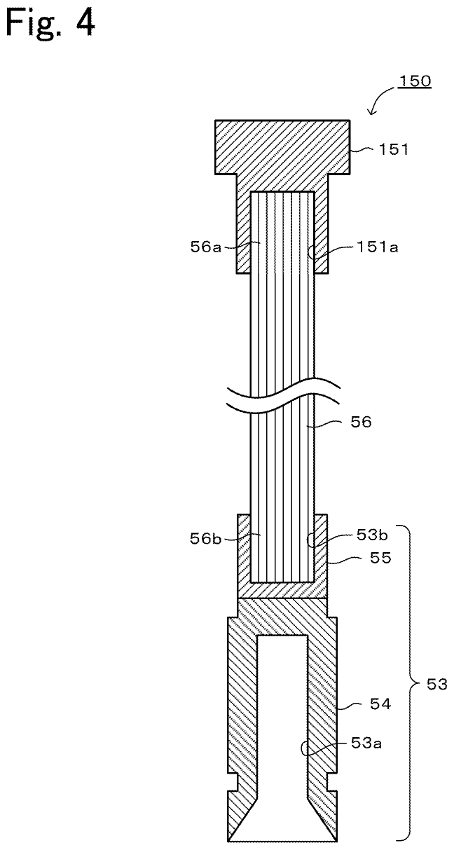

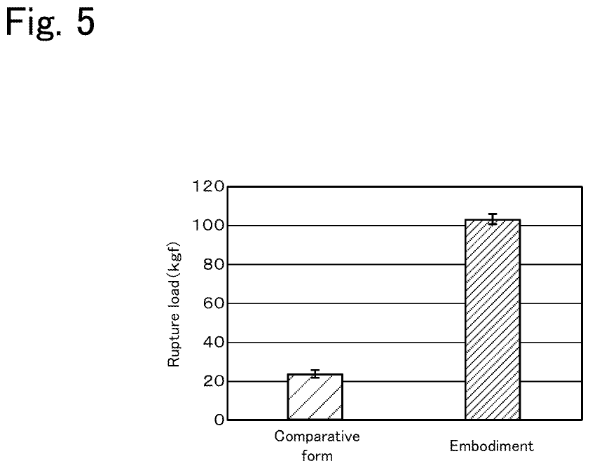

Next, the rupture strength of the feeder member 50 joined to an electrode of the wafer placement table 10 is described. The electrode-side terminal 51 of the feeder member 50 was made of Mo, and the insert 52, the connector 53 (the lower member 54 and the upper member 55), and the cable 56 were made of Cu. The feeder member 50 was manufactured in accordance with the manufacturing example above, and was attached to the electrode. Note that when a joined part where the joined portion 52a of the insert 52 and the electrode-side terminal 51 were joined to each other was seen in a SEM photograph, a gap was not seen at a joining interface. For comparison, a feeder member 150 shown in FIG. 4 was formed, and the rupture strength when the feeder member 150 was joined to an electrode of the wafer placement table 10 was also measured. The feeder member 150 was formed in the same way as the feeder member 50, except that an electrode-side terminal 151 that was one-piece body having the electrode-side terminal 51 and the insert 52, that was made of Mo, and that had a hole was used, and except that, with an upper end 56a of the cable 56 being inserted into a hole 151a of the electrode-side terminal 151 having the hole, they were joined to each other by electron-beam welding. The feeder member 150 was attached to the electrode of the wafer placement table 10. The rupture strengths of the present embodiment and the comparative form were measured under the same conditions in conformity with “JIS Z 2241: Metallic Materials Tensile Testing Method”. The results are shown in FIG. 5. FIG. 5 shows that the rupture strength of the present embodiment is increased to approximately four times the rupture strength of the comparative form. In the comparative form, a joint where the electrode-side terminal 151 having the hole and the cable 56 were joined to each other was disjoined and ruptured, whereas, in the present embodiment, the cable 56 itself ruptured. In addition, in the comparative form, a gap (a pore) was seen at a joining interface between the electrode-side terminal 151 having the hole and the cable 56.

In the feeder member 50 described in detail above, the joined portion 52a of the insert 52 made of a Cu containing material is directly joined without using a brazing material to the electrode-side terminal 51 made of a high-melting-point metal containing material. Therefore, the electrode-side terminal 51 and the insert 52 are joined to each other with sufficient strength. The upper end 56a of the cable 56 made of a Cu containing material is joined with the upper end 56a being inserted in the hole portion 52b of the insert 52, and the lower end 56b of the cable 56 is joined with the lower end 56b being inserted in the recessed portion 53b of the connector 53 made of a Cu containing material. Since these joinings are joinings between members made of a Cu containing material, sufficient strength can be obtained. Therefore, the feeder member 50 has sufficient strength. As a result, the feeder member 50 can be used without any problem even if the upper limit of the operating temperature of the wafer placement table 10 is set at a high temperature (such as 300° C.)

The electrode-side terminal 51 is preferably a Mo containing material. This makes it possible to, when the ceramic base 20 is an alumina containing material, prevent, for example, a crack from being formed between the electrode-side terminal 51 and the ceramic base 20. This is because, since the coefficient of thermal expansion of alumina and the coefficient of thermal expansion of Mo are close to each other, stress that is produced by a difference in thermal expansion is reduced.

Note that the present invention is not limited in any way to the embodiment above, and it goes without saying that the present invention can be carried out in various modes as long as the modes pertain to the technical scope of the present invention.

For example, in the embodiment above, although the connector 53 is formed by soldering or welding the lower member 54 and the upper member 55 to each other, the connector 53 may be formed as one-piece instead of being formed by joining a plurality of members in this way. This makes it unnecessary for the manufacturing process of the feeder member 50 to include a step of soldering or welding the lower member 54 and the upper member 55 to each other.

In the embodiment above, the connector 53 of the feeder member 50A may be fixed to the insulating tube 42, or the connector 53 of the feeder member 50B may be fixed to the insulating tube 44.

In the embodiment above, although the electrostatic electrode 22 and the heater electrode 24 are embedded in the ceramic base 20, either one of them may be embedded in the ceramic base 20. In addition, it is possible to embed a plasma-generation electrode in the ceramic base 20 and attach the feeder member 50 to this electrode in the same way as in the embodiment above.

In the embodiment above, although the connector 53 has a socket portion 53a that is a banana jack, the connector 53 may have a banana plug instead of the socket portion 53a. In this case, the banana plug of the connector 53 is inserted into a banana jack that is a conductive member of an external device (for example, the direct-current power source 62 or the heater power source 64).

In the embodiment above, although the joined layer 40 is a metal joined layer, the joined layer 40 may be a resin adhesive layer.

The present application claims priority from Japanese Patent Application No. 2022-032564, filed on Mar. 3, 2022, the entire contents of which are incorporated herein by reference.

What is claimed is:

1. A feeder member that is used to supply electricity to an electrode embedded in a ceramic base, the feeder member comprising:
an electrode-side terminal that is made of a high-melting-point metal containing material, and that is joined to the electrode;
an insert that is made of a Cu containing material, and that has a joined portion and a hole portion, the joined portion being directly joined to the electrode-side terminal without using a brazing material, the hole portion being provided on a side opposite to the joined portion;
a connector that is made of a Cu containing material, and that has a joint portion and a recessed portion, the joint portion being electrically connected to a conductive member differing from the feeder member, the recessed portion being provided on a side opposite to the joint portion; and
a cable that is made of a Cu containing material, has one end joined to the insert with the one end being inserted in the hole portion of the insert, and has the other end joined to the connector with the other end being inserted in the recessed portion of the connector.

2. The feeder member according to claim 1, wherein the electrode-side terminal is made of a Mo containing material.

3. A wafer placement table comprising:
a ceramic base that has, at a surface thereof, a wafer placement surface;
an electrode that is embedded in the ceramic base; and
a feeder member that is inserted into a surface of the ceramic base on a side opposite to the wafer placement surface, and that is joined to the electrode,
wherein the feeder member is the feeder member according to claim 1, and the electrode-side terminal is joined to the electrode.

4. The wafer placement table according to claim 3, wherein the ceramic base is made of an alumina containing material, and
wherein the electrode-side terminal is made of a Mo containing material.
